(19) United States
(12) Patent Application Publication
(10) Pub. No.: US 2016/0215211 A1
(43) Pub. Date: Jul. 28, 2016

(54) IMPROVED GARNET LUMINOPHORE AND PROCESS FOR PRODUCTION THEREOF AND LIGHT SOURCE

(71) Applicant: LEUCHTSTOFFWERK BREITUNGEN GMBH, Breitungen (DE)

(72) Inventor: Hans-Juergen LIMBURG, Tiefenort (DE)

(21) Appl. No.: 14/915,540

(22) PCT Filed: Aug. 26, 2014
(86) PCT No.: PCT/EP2014/068034

§ 371 Date: Feb. 29, 2016

(30) Foreign Application Priority Data
Aug. 28, 2013 (DE) 10 2013 109 313.2

(51) Int. Cl. C09K 11/77; H01L 33/50

(52) U.S. Cl. CPC C09K 11/7774; H01L 33/504

(57) ABSTRACT

The present invention relates to an improved garnet luminophore which can be excited in a first wavelength range by electromagnetic radiation, as a result of which electromagnetic radiation can be emitted by the garnet luminophore in a second wavelength range. The invention additionally relates to a process for production of an improved garnet luminophore and to a light source comprising the garnet luminophore of the invention. The garnet luminophore has been activated with trivalent cerium and has a host lattice of the general chemical formula (LuₓY_{y}Gd_{z}AKₖ)₃(Al_{b}B_{c}P_{d}) (OₑX_{f})₁₂ where AK=Li, Na and/or K; B=Ga and/or In; and X=F, Cl and/or Br.

### FIELD

The present invention relates to an improved garnet luminophore which can be excited in a first wavelength range by electromagnetic radiation, as a result of which electromagnetic radiation can be emitted by the garnet luminophore in a second wavelength range. The invention further relates to a process for the production of an improved garnet luminophore and to a light source comprising the garnet luminophore of the invention.

### BACKGROUND

Document WO 87/02374 A1 shows garnet luminophore particles of the formula Y₃Al₅O₁₂ which are bound with a sulfate.

Document JP 10242513 A shows garnet luminophores of the general chemical formulas (RE₁₋ₓSmₓ)₃(Al_{y}Ga_{1-y})₅O₁₂:Ce and (YᵣGd₁₋ᵣ)₃Al₅O₁₂: Ce.

Document WO 2012/009455 A1 shows modified garnet luminophores of the general chemical formula:

(Lu_{1-a-b-c}YₐTb_{1-b}A_{c})₃(Al_{1-d}B_{d})₅(O₁₋ₑCₑ)₁₂: Ce,Eu

wherein A=Mg, Sr, Ca, Ba; B=Ga, In; C=F, Cl, Br;
as well as:

(Y,A)₃(Al,B)₅(O,C)₁₂:Ce

wherein A=Tb, Gd, Sm, La, Lu, Sr, Ca, Mg; B=Si, Ge, B, P, Ga.

U.S. Pat. No. 5,988,925 shows garnet luminophores of the general chemical formula:

(RE₁₋ᵣSmᵣ)₃(Al₁₋ₛGaₛ)₅O₁₂:Ce

wherein RE=Y, Gd.

Document WO 01/08453 A1 teaches garnet luminophores of the general chemical formula:

(Tb_{1-x-y}SEₓCe_{y})₃(Al,Ga)₅O₁₂

wherein SE=Y, Gd, La, Sm, Lu.

The incorporation of Tb is intended to shift the emission wavelength, particularly to be able to produce luminophores for white LEDs.

EP 2 253 689 A2 shows luminophores of the general chemical formula:

a(M¹O).b(M²₂O).c(M²X).dAl₂O₃.e(M³O).f(M⁴₂O₃).g(M⁵ₒOₚ).h(M⁶ₓO_{y})

wherein M¹=Cu, Pb; M²=Li, Na, K, Rb, Cs, Au, Ag;

### M³=Be, Mg, Ca, Sr, Ba, Zn, Cd, Mn;

M⁴=Sc, B, Ga, In; M⁵=Si, Ge, Ti, Zr, Mn, V, Nb, Ta, W, Mo;

### M⁶=Bi, Sn, Sb, Sc, Y, La, Ce, Pr, Nd, Pm, Sm, Eu, Gd, Tb, Dy, Ho, Er, Tm, Yb, Lu.

Among others, Cu_{0.2}Mg_{1.7}Li_{0.2}Sb₂O₇:Mn and Cu_{0.02}Ca_{4.98}(PO₄)₃Cl:Eu are given as specific examples. The wildcard symbol M⁶ represents the activator, which may. for example, be Y, Ce, Eu, or Gd. The host lattice can include M¹, M², M³, M⁴, and M⁵, wherein these wildcard symbols do not represent, inter alia, Lu, Y, and Gd.

Garnet luminophores of the following general chemical formula are known from U.S. Patent No. 2005/0093442 A1:

(Tb_{1-x-y-z-w}YₓGd_{y}Lu_{z}Ce_{w})₃MᵣAl₅₋ᵣO_{12+δ}

wherein M=Sc, In, Ga, Zn, Mg.

U.S. Patent No. 2004/0173807 A1 shows garnet luminophores of the general chemical formula:

RE₃(Al₁₋ₛGaₛ)₅O₁₂:Ce:xMAl₂O₄

wherein RE=Y, Gd, Sm, Lu, Yb; and M is an alkaline metal or alkaline earth metal. The variable x ranges from 0.01 to 1.0%. This patent specification does not provide specific examples of this luminophore. The only example provided for M is Ba, such that the luminophore is doped with a small quantity of BaAl₂O₄.

U.S. Patent No. 2007/0273282 A1 relates in particular to a LED emitting white light. The patent specifies the most varies conversion luminophores for producing white light, e.g. Sr₂P₂O₇:Eu²⁺,Mn²⁺ and Be₂P₂O₇:Eu²⁺,Mn²⁺, which are alkaline earth metal diphosphates.

Document CN 1 733 865 A shows a luminophore of the formula Y₃Al₅O₁₂:Ce,Li, which is also specified as Y_{2.95}Ce_{0.01}Li_{0.04}Al₅O₁₂.

Document CN 102 173 773 A discloses a YAG luminophore co-doped with Ce, Li, which is also designated as Y_{2.95}Ce_{0.01}Li_{0.04}Al₅O₁₂.

Document CN 101 760 197 A shows a luminophore of the formula Y_{2.94}Al₅(O,F)₁₂:0.06Ce and a luminophore of the formula Y_{2.92}Al_{4,8}Li_{0.1}V_{0.1}(O,F)₁₂:0.08Ce. It should be pointed out that the insertion of Ti, Zr, V, Mn, Zn, Mg, or Li into a YAG luminophore results in emission in other wavelength ranges.

### SUMMARY

The problem of the present invention, starting from prior art, is to provide a modified and improved garnet luminophore whose emission wavelength changes over a large range as a function of the concentration of the ingredients of the garnet luminophore. Furthermore, a method for producing an improved garnet luminophore as well as a light source with an improved garnet luminophore are to be provided.

This problem is solved by a garnet luminophore according to the appended claim 1. The problem is further solved by a method for producing an improved garnet luminophore according to the appended independent claim 7 and a light source according to the appended independent claim 8.

The garnet luminophore according to the invention is a conversion luminophore. Therefore, the garnet luminophore can be excited by electromagnetic radiation in a first wavelength range. The electromagnetic radiation in a first wavelength range can particularly be light or UV radiation. As a result of the excitation, the garnet luminophore can emit electromagnetic radiation in a second wavelength range. The electromagnetic radiation in a second wavelength range can particularly be light or IR radiation. The first wavelength range is preferably different from the second wavelength range.

The garnet luminophore is activated using trivalent cerium. For this purpose, small quantities of cerium are doped into a host lattice of the garnet luminophore. Other ions can be doped as coactivators into the host lattice of the garnet luminophore.

The host lattice of the garnet luminophore has the following general chemical formula:

(LuₓY_{y}Gd_{z}AKₖ)₃(Al_{b}B_{c}P_{d})₅(OₑX_{f})₁₂

In this formula, AK stands for one or several alkaline metals selected from the group including the elements Li, Na, and K. The wildcard symbol B represents Ga, In, or a mixture of these elements. The wildcard symbol X stands for one or several halogens selected from the group including the elements F, Cl, and Br.

The variables x, y, and z are each greater than or equal to zero and smaller than one. The variable k is greater than zero, meaning that the alkaline metal is in principle contained in the luminophore. The variable k is smaller than one. The sum total of the variables x, y, z, and k is one. The variables b and c are each greater than or equal to zero and smaller than one. The sum total of variables b and c is greater than zero and preferably smaller than 0.5. The variable d is greater than or equal to zero and smaller than one. The sum total of variables b, c, and d is smaller than or equal to one. The variable e is greater than zero and smaller than or equal to one. The variable e is preferably greater than 0.5. The variable f is greater than or equal to zero and smaller than one. The sum total of variables e and f is smaller than or equal to one.

The garnet luminophore according to the invention is characterized in that one or several multivalent alkaline metals Li, Na, and K are incorporated into the host lattice. The wavelength of the garnet luminophore according to the invention can be influenced by the selection of the incorporated alkaline metal and its proportion k. The incorporation of Li as an alkaline metal results in a green shift of the emission due to the smaller ion radius of Li, while the incorporation of Na and/or K as alkaline metal facilitates a red shift depending on the ion radius of the respective alkaline metal. The respective shift increases with the proportion k of the alkaline metal across a relevant range.

Different nomenclatures for representing luminophores have been established in luminophore technology. In simplified formula representations, the concentration of the activator is not specified quantitatively, such that it is not taken into consideration for the index of the reduced proportion of the regular lattice component. According to such a simplified nomenclature, the garnet luminophore according to the invention can be specified as follows:

(LuₓY_{y}Gd_{z}AKₖ)₃(Al_{b}B_{c}P_{d})₅(OₑX_{f})₁₂:Ce

The wildcard symbols AK, B, and X stand for the same elements as in the formula specified above for the host lattice. The variables x, y, z, k, b, c, d, e, and f have the same value ranges as in the formula specified above for the host lattice.

In a more precise nomenclature for representing luminophores, the proportion of the activator is quantitatively taken into account. According to such a nomenclature, the garnet luminophore according to the invention can be specified as follows:

(Lu_{x′}Y_{y′}Gd_{z′}AK_{k′})₃(Al_{b}B_{c}P_{d})₅(OₑX_{f})₁₂:Ceₐ

The wildcard symbols AK, B, and X stand for the same elements as in the formula specified above for the host lattice. The variables b, c, d, e, and f have the same value ranges as in the formula specified above for the host lattice. The variables x′, y′, and z′ are each greater than or equal to zero and smaller than or equal to (1−a−k′), wherein k′ is greater than zero and smaller than (1−a). The sum total of the variables x′, y′, z′, and k′ is (1−a).

The proportion of the activator cerium is generally greater than zero. This proportion is preferably smaller than or equal to 0.4. For the formula of the garnet luminophore according to the invention provided above, the variable a for the cerium proportion is accordingly greater than zero and preferably smaller than or equal to 0.4. It is further preferred that the proportion of the activator cerium is between 0.005 and 0.15.

The garnet luminophore according to the invention can also contain small proportions of other chemical elements as long as these do not prevent but at best slightly influence the emission, which, according to the invention, is caused by the cerium in the specified host lattice.

In a first group of preferred embodiments of the garnet luminophore according to the invention, the host lattice contains the halogen X. The host lattice does not include phosphorus, such that the variable d is equal to zero and the sum total of the variables b and c is one. The variable f is a quarter of the variable k. The variable e is one minus three eighths of the variable k. The resulting general chemical formula of the host lattice is:

(LuₓY_{y}Gd_{z}AKₖ)₃(Al_{b}B_{1-b})₅(O_{1-(3/8)k}X_{k/4})₁₂.

In a second group of preferred embodiments of the garnet luminophore according to the invention, the host lattice contains phosphorus. The host lattice does not include the halogen X, such that the variable f is equal to zero and the variable e is equal to one. The variable d is one third of the variable k. The variable b is one minus the variable c and minus seven forty-fifths of the variable k. The resulting general chemical formula of the host lattice is:

(LuₓY_{y}Gd_{z}AKₖ)₃(Al_{1-c-(7/45)k}B_{c}P_{k/3})₅O₁₂.

In principle, AK can be formed by one of the alkaline metals Li, Na, and K, of which several examples are given below:

(Lu_{0.9}Li_{0.1})₃Al₅(O_{0.9625}F_{0.025})₁₂:Ce

(Y_{0.95}Na_{0.05})₃Al₅(O_{0.98125}F_{0.0125})₁₂:Ce

(Y_{0.99}K_{0.01})₃Al₅(O_{0.9625}F_{0.0025})₁₂:Ce

The alkaline metal AK can also be formed by several of the alkaline metals Li, Na, or K. It is further preferred that the alkaline metal is formed either by Li, by Na, or by K. These alkaline metals are particularly well suited for incorporation into the host lattice.

In particularly preferred embodiments, the alkaline metal is formed by Li, which reduces the emission wavelength of the garnet luminophore.

In other particularly preferred embodiments, the alkaline metal is formed by Na, which increases the emission wavelength of the garnet luminophore.

In principle, X can be formed by one of the halogens F, Cl, and Br, of which several examples are given below:

(Lu_{0.91}Li_{0.1})₃Al₅(O_{0.9625}F_{0.025})₁₂:Ce

(Y_{0.95}Na_{0.05})₃Al₅(O_{0.98125}Cl_{0.0125})₁₂:Ce

(Y_{0.99}Na_{0.01})₃Al₅(O_{0.99625}Br_{0.0025})₁₂:Ce

The halogen X can be formed by F, Cl, or Br or a mixture of these elements. It is preferred that the halogen X is formed either by F or by Cl or by Br.

In particularly preferred embodiments, the halogen X is formed by F, which makes the synthesis of the garnet luminophore easier.

The first group of preferred embodiments just includes Lu of the rare earth metals Lu, Y, and Gd, such that y=z=0 and x=1 k, which results in the general formula (Lu₁₋ₖAKₖ)₃(Al_{b}B_{c}P_{d})₅(OₑX_{f})₁₂ of the host lattice. An example of this luminophore is (Lu_{0.9}Li_{0.1})₃Al₅(O_{0.9625}F_{0.025})₁₂:Ce. In this first group of preferred embodiments, the alkaline metal preferably is Li. This causes a green shift of the emission.

The second group of preferred embodiments just includes Y of the rare earth metals Lu, Y, and Gd, such that x=z=0 and y=1 k, which results in the general formula (Y₁₋ₖAKₖ)₃(Al_{b}B_{c}P_{d})₅(OₑX_{f})₁₂ of the host lattice. An example of this luminophore is (Y_{0.95}Li_{0.05})₃Al₅(O_{0.98125}F_{0.0125})₁₂:Ce. In this second group of preferred embodiments, the alkaline metal preferably is Li. This causes a green shift of the emission. Alternatively, the alkaline metal preferably is Na in this second group of preferred embodiments. This causes an orange shift of the emission.

A third group of preferred embodiments only includes Y and Gd of the rare earth metals Lu, Y, and Gd, such that x=0 and y+z=1−k, which results in the general formula (Y_{y}Gd_{z}AKₖ)₃(Al_{b}B_{c}P_{d})₅(OₑX_{f})₁₂ of the host lattice. Examples of this luminophore are (Y_{0.45}Gd_{0.45}Na_{0.1})₃Al₅(O_{0.95}F_{0.05})₁₂:Ce and (Y_{0.45}Gd_{0.45}Na_{0.05})₃Al₅(O_{0.98125}Cl_{0.0125})₁₂:Ce. In this third group of preferred embodiments, the alkaline metal preferably is Na. This causes an orange shift of the emission.

A fourth group of preferred embodiments only includes Lu and Gd of the rare earth metals Lu, Y, and Gd, such that y=0 and x+z=1−k, which results in the general formula (Lu_{y}Gd_{z}AKₖ)₃(Al_{b}B_{c}P_{d})₅(OₑX_{f})₁₂ of the host lattice. An example of this luminophore is (Lu_{0.75}Gd_{0.15}Li_{0.1})₃Al₅(O_{0.9625}F_{0.025})₁₂:Ce. In this fourth group of preferred embodiments, the alkaline metal preferably is Li.

The proportion k of the alkaline metal preferably is between 0.0025 and 0.2. The proportion f of the halogen X preferably is between 0.000625 and 0.05.

The aluminum that is present in the host lattice can be partially or fully replaced by the wildcard symbol B. Replacement of Al by In and/or Ga results in a reduction of the emission wavelength of the garnet luminophore. An example of this is:

(Lu_{0.9}Li_{0.1})₃(Al_{0.9}Ga_{0.1})₅(O_{0.9625}F_{0.025})₁₂:Ce

It is preferred that Al is only partially replaced with B, such that c<1, more preferred c<0.4. In alternative preferred embodiments, Al is not replaced with B, such that c=0.

Examples from the second group of preferred embodiments

are:

(Y_{0.9}Li_{0.1})₃(Al_{0.984}P_{0.033})₅O₁₂:Ce

(Lu_{0.9}Li_{0.1})₃(Al_{0.9841}P_{0.033})₅O₁₂:Ce

The first wavelength range preferably ranges from 250 nm to 500 nm.

A mean wavelength of the first wavelength range at which there is maximum excitation of the garnet luminophore, preferably is in the blue spectral region of the light spectrum.

A mean wavelength of the second wavelength range at which there is maximum emission of the garnet luminophore, preferably is between 480 nm and 630 nm, particularly preferably between 500 nm and 600 nm.

The method according to the invention is used to produce an improved garnet luminophore. The garnet luminophore to be produced is a conversion luminophore. Therefore, the garnet luminophore to be produced can be excited by electromagnetic radiation in a first wavelength range. The electromagnetic radiation in a first wavelength range can particularly be light or UV radiation. As a result of the excitation, the garnet luminophore can emit electromagnetic radiation in a second wavelength range. The electromagnetic radiation in a second wavelength range can particularly be light or IR radiation.

The method according to the invention first includes a step in which at least one chemical compound that includes Lu, Y, and/or Gd is provided. In addition at least one chemical compound is provided that includes Al, Ga, and/or In. At least one of the compounds mentioned is made up by an oxide. The compounds mentioned are preferably made up by oxalates, carbonates, halides, and/or oxides. All compounds made up by oxides are particularly preferred.

In another step, a chemical compound is provided that includes cerium; preferably cerium oxide or cerium oxalate.

Furthermore, a chemical compound of the general chemical formula AKX is provided. In this formula, the wildcard symbol AK stands for one or several alkaline metals selected from the group including the elements Li, Na, and K. The wildcard symbol X stands a halogen selected from the group including the elements F, Cl, and Br or for a phosphate. The chemical compound AKX has a dual function in the method according to the invention. It represents a parent compound whose ingredients will be contained in the later reaction product, that is, the garnet luminophore. AKX also acts as a fluxing agent.

In another step of the method according to the invention, the chemical compounds provided are ground and mixed together. The mixture is then heated to a temperature of more than 1,400° C., preferably to more than 1,600° C., by which the ingredients of the mixture react to form a garnet luminophore. Heating is preferably performed in a reducing atmosphere. Finally, the garnet luminophore must be cooled.

The method according to the invention is preferably used to produce the garnet luminophore according to the invention. It is particularly preferred to use the method according to the invention for producing preferred embodiments of the luminophore according to the invention.

The light source according to the invention includes the garnet luminophore according to the invention. Furthermore, the light source according to the invention includes a radiation source for emitting an electromagnetic radiation in the first wavelength range. The radiation source preferably is a semiconductor element for converting electrical energy into electromagnetic radiation, particularly an electromagnetic luminophore such as a nitride luminophore. The radiation source can preferably emit light in the blue spectral region of the light spectrum. Accordingly, the first wavelength range preferably includes the blue spectral region of the light spectrum. The radiation source and the garnet luminophore are disposed in the light source in such a manner that the radiation that can be emitted from the radiation source hits the garnet luminophore to be able to excite it. The radiation source and the garnet luminophore are preferably disposed in the light source in such a manner that a mixture of the radiation that can be emitted from the radiation source and the radiation that can be emitted by the garnet luminophore can exit from the light source. The mixture of the radiation that can be emitted from the radiation source and the radiation that can be emitted by the garnet luminophore preferably is white light.

In preferred embodiments of the light source according to the invention, the second wavelength range of the garnet luminophore has a mean wavelength in the green, yellow, or orange spectral regions of the light spectrum. It is particularly preferred that green light can be emitted from the garnet luminophore. The mean wavelength preferably is smaller 550 nm, particularly preferably smaller than 530 nm. The light source further includes a second conversion luminophore that can be excited by the radiation emittable from the radiation source, whereby electromagnetic radiation in the orange and/or red spectral regions of the light spectrum can be emitted from the second conversion luminophore. The radiation of the radiation source, which preferably is light in the blue spectral region of the light spectrum, the green radiation of the garnet luminophore, and the orange and/or red radiation of the second conversion luminophore, when mixed, result in a white light with a high color rendering index.

In an alternative preferred embodiment of the light source according to the invention, the second wavelength range has a mean wavelength in the yellow spectral region of the light spectrum while the radiation of the radiation source is light in the blue spectral region of the light spectrum. It is preferred in this embodiment of the light source according to the invention that no other conversion luminophore is present.

The light source according to the invention is preferably formed by a LED or a LED backlight for a liquid crystal display.

### BRIEF DESCRIPTION OF THE DRAWINGS

Other advantages, details and further developments of the invention can be derived from the description of referred embodiments below with reference to the drawing:

FIG. 1: shows emission spectra of preferred embodiments of the garnet luminophore according to the invention with a host lattice of the following composition:

(Lu₁₋ₖLiₖ)₃Al₅(O_{1-(3/8)·k}F_{k/4})₁₂

FIG. 2 shows excitation spectra of the embodiments characterized in FIG. 1.

FIG. 3 shows more excitation spectra of the embodiments characterized in FIG. 1.

FIG. 4 shows emission spectra of preferred embodiments of the garnet luminophore according to the invention with a host lattice of the following composition:

(LuₓGd_{z}Liₖ)₃Al₅(O_{1-(3/8)·k}F_{k/4})₁₂.

FIG. 5 shows excitation spectra of the embodiments characterized in FIG. 4.

FIG. 6 shows more excitation spectra of the embodiments characterized in FIG. 4.

FIG. 7 shows emission spectra of preferred embodiments of the garnet luminophore according to the invention with a host lattice of the following composition:

(Y₁₋ₖNaₖ)₃Al₅(O_{1-(3/8)·k}F_{k/4})₁₂.

FIG. 8 shows excitation spectra of the embodiments characterized in FIG. 7.

### DETAILED DESCRIPTION

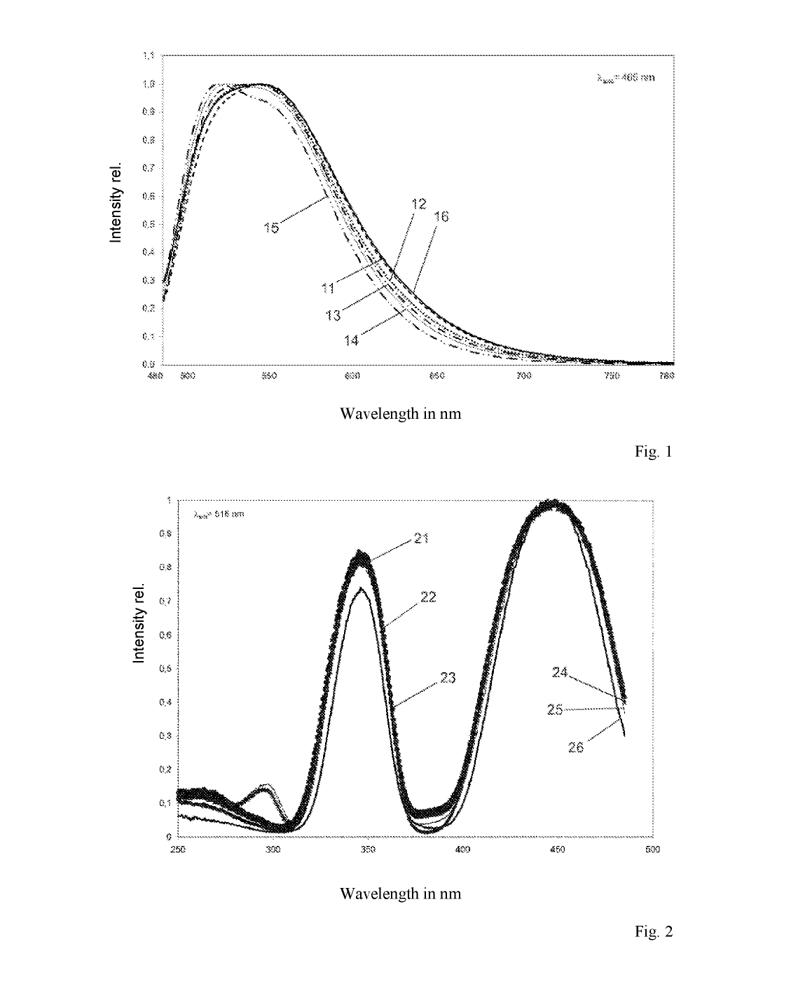

FIG. 1 to FIG. 3 relate to preferred embodiments of the garnet luminophore according to the invention which have a host lattice of the general chemical formula (Lu₁₋ₖLiₖ)₃Al₅(O_{1-(3/8)·k}F_{k/4})₁₂ and are doped with cerium as an activator at a mole fraction of 0.014.

Various quantities of Lu₂O₃, CeO₂, Al₂O₃, and LiF were weighed and subsequently intermixed to produce these embodiments. These mixtures were annealed at a temperature of about 1,650° C., whereby these luminophores were formed. It was particularly the LiF content that was varied in this series of embodiments. The weighed quantities of the parent substances are listed in Table 1 [and] Table 3.

TABLE 1

| Lu₂O₃ | CeO₂ | Al₂O₃ | LiF | LiF | Σ |
|---|---|---|---|---|---|
| in g | in g | in g | in g | in % | in g |
| 141.253 | 1.735 | 61.177 | 1.021 | 0.50 | 205.185 |
| 139.291 | 1.711 | 60.327 | 2.517 | 1.25 | 203.846 |
| 137.329 | 1.687 | 59.477 | 4.962 | 2.50 | 203.456 |
| 135.367 | 1.663 | 58.628 | 9.783 | 5.00 | 205.441 |
| 129.482 | 1.590 | 56.079 | 18.715 | 10.0 | 205.866 |
| 141.253 | 1.735 | 61.177 | 0 | 0 | 204.165 |

FIG. 1 shows emission spectra of a series of these embodiments in which the proportions of Li and F vary, and for comparison an emission spectrum of an embodiment outside the invention for the production of which no LiF was present in the mixture, but which was otherwise similar in quality to the mixture described. Excitation was performed using a radiation of a wavelength of 465 nm. Table 2 shows the assignment of the various embodiments with different LiF proportions in the mixture to the respective spectra marked with reference numbers.

FIG. 2 shows excitation spectra of the series of embodiments described in which the proportions of Li and F vary. These excitation spectra are in relation to an emission wavelength of 515 nm. Table 2 again shows the assignment of the various embodiments to the respective spectra marked with reference numbers.

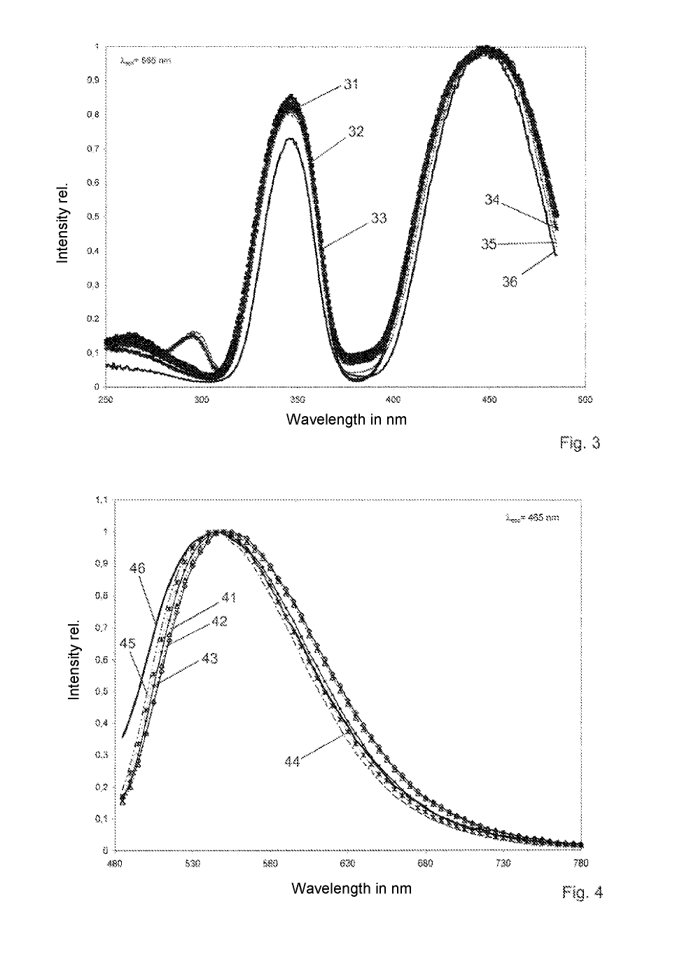

FIG. 3 shows other excitation spectra of the series of embodiments described in which the proportions of Li and F vary. These excitation spectra are in relation to an emission wavelength of 555 nm. Table 2 again shows the assignment of the various embodiments to the respective spectra marked with reference numbers.

TABLE 2

| Proportion | Reference | Reference | Reference |
|---|---|---|---|
| of LiF | number | number | number |
| in % | in FIG. 1 | in FIG. 2 | in FIG. 3 |
| 0.50 | 11 | 21 | 31 |
| 1.25 | 12 | 22 | 32 |
| 2.50 | 13 | 23 | 33 |
| 5.00 | 14 | 24 | 34 |
| 10.0 | 15 | 25 | 35 |
| 0 | 16 | 26 | 36 |

FIG. 4 to FIG. 6 relate to preferred embodiments of the garnet luminophore according to the invention which have a host lattice of the general chemical formula (LuₓGd_{z}Liₖ)₃Al₅(O_{1-(3/8)·k}F_{k/4})₁₂ and are doped with cerium as an activator at a mole fraction of 0.050.

Various quantities of Gd₂O₃, CeO₂, Al₂O₃, and LiF were weighed and subsequently intermixed to produce these embodiments. Then a quantity of Lu₂O₃ was weighed and mixed with the respective mixture. These mixtures were annealed at a temperature of about 1,650° C., whereby these luminophores were formed. It was particularly the LiF content that was varied in this series of embodiments. The weighed quantities of the parent substances are listed in Table 3.

TABLE 3

| Lu₂O₃ | Gd₂O₃ | CeO₂ | Al₂O₃ | LiF | LiF | Σ |
|---|---|---|---|---|---|---|
| in g | in g | in g | in g | in g | in % | in g |
| 128.933 | 6.525 | 6.196 | 61.177 | 1.014 | 0.50 | 203.845 |
| 127.142 | 6.434 | 6.110 | 60.327 | 2.500 | 1.25 | 202.514 |
| 125.351 | 6.344 | 6.024 | 59.477 | 4.930 | 2.50 | 202.126 |
| 122.665 | 6.208 | 5.895 | 58.203 | 9.649 | 5.00 | 202.619 |
| 117.293 | 5.936 | 5.637 | 55.654 | 18.452 | 10.0 | 202.972 |
| 128.933 | 6.525 | 6.196 | 61.177 | 0 | 0 | 202.831 |

FIG. 4 shows emission spectra of this series of embodiments in which the proportions of Li and F vary, and for comparison an emission spectrum of an embodiment outside the invention for the production of which no LiF was present in the mixture. Excitation was performed using a radiation of a wavelength of 465 nm. Table 4 shows the assignment of the various embodiments with different LiF proportions in the mixture to the respective spectra marked with reference numbers.

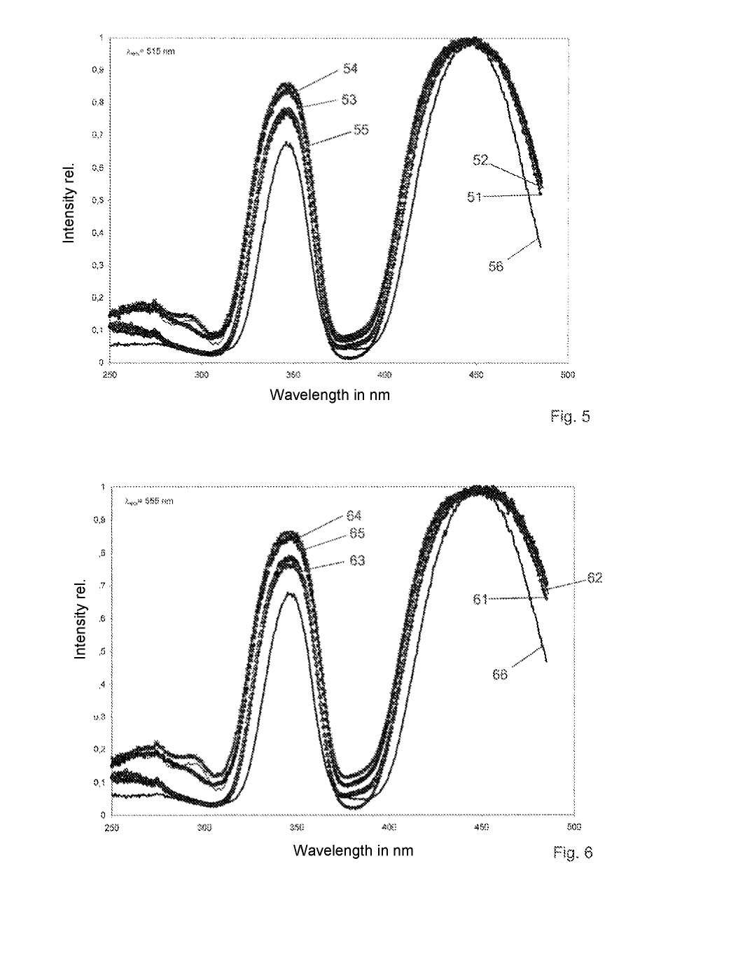

FIG. 5 shows excitation spectra of the series of embodiments described in which the proportions of Li and F vary. These excitation spectra are in relation to an emission wavelength of 515 nm. Table 4 again shows the assignment of the various embodiments to the respective spectra marked with reference numbers.

FIG. 6 shows other excitation spectra of the series of embodiments described in which the proportions of Li and F vary. These excitation spectra are in relation to an emission wavelength of 555 nm. Table 4 again shows the assignment of the various embodiments to the respective spectra marked with reference numbers.

TABLE 4

| Proportion | Reference | Reference | Reference |
|---|---|---|---|
| of LiF | number | number | number |
| in % | in FIG. 4 | in FIG. 5 | in FIG. 6 |
| 0.50 | 41 | 51 | 61 |
| 1.25 | 42 | 52 | 62 |
| 2.50 | 43 | 53 | 63 |
| 5.00 | 44 | 54 | 64 |
| 10.0 | 45 | 55 | 65 |
| 0 | 46 | 56 | 66 |

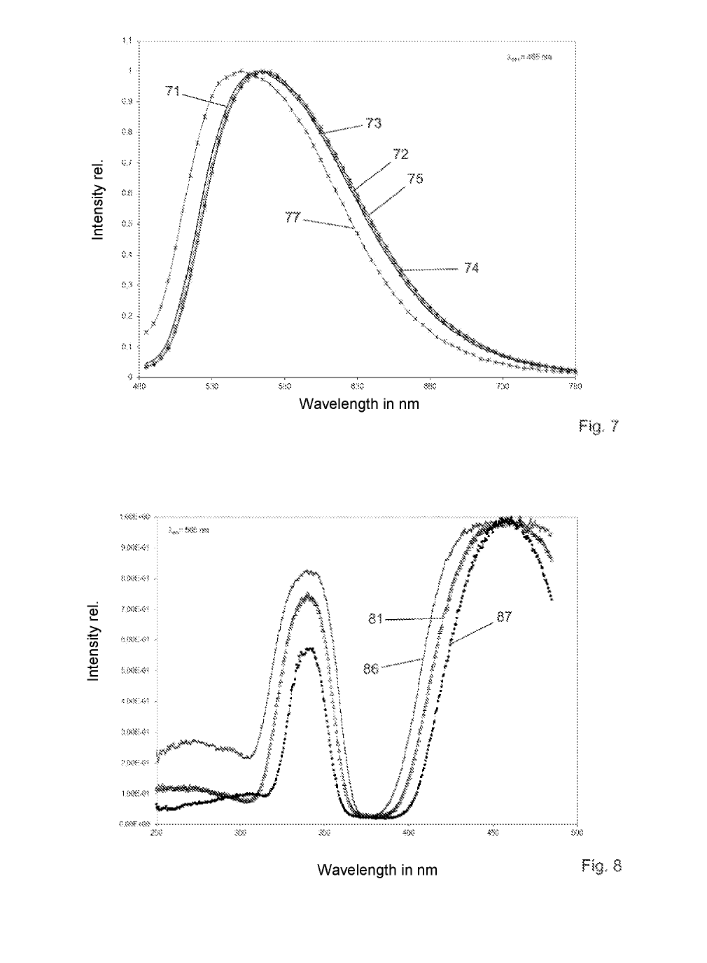

FIG. 7 and FIG. 8 relate to other preferred embodiments of the garnet luminophore according to the invention which have a host lattice of the general chemical formula (Y₁₋ₖNaₖ)₃Al₅(O_{1-(3/8)·k}F_{k/4})₁₂ and are doped with cerium as an activator at a mole fraction of 0.040.

Various quantities of CeO₂, Al₂O₃, and NaF were weighed and subsequently intermixed to produce these embodiments. Then a quantity of Y₂O₃ was weighed and mixed with the respective mixture. These mixtures were annealed at a temperature of about 1,675° C., whereby these luminophores were formed. It was particularly the NaF content that was varied in this series of embodiments. The weighed quantities of the parent substances are listed in Table 5.

TABLE 5

| Y₂O₃ | CeO₂ | Al₂O₃ | NaF | NaF | Σ |
|---|---|---|---|---|---|
| in g | in g | in g | in g | in % | in g |
| 217.861 | 13.838 | 170.785 | 1.006 | 0.25 | 403.491 |
| 216.778 | 13.770 | 169.936 | 2.002 | 0.50 | 402.485 |
| 216.778 | 13.770 | 169.936 | 3.004 | 0.75 | 403.486 |
| 215.694 | 13.701 | 169.086 | 3.985 | 1.00 | 402.465 |
| 216.778 | 13.770 | 169.936 | 4.606 | 1.15 | 405.088 |
| 215.152 | 13.666 | 168.661 | 5.962 | 1.50 | 403.461 |
| 218.945 | 13.907 | 171.635 | 0 | 0 | 404.488 |

FIG. 7 shows emission spectra of this series of embodiments in which the proportions of Na and F vary, and for comparison an emission spectrum of an embodiment outside the invention for the production of which no NaF was present in the mixture. Excitation was performed using a radiation of a wavelength of 465 nm. Table 6 shows the assignment of the various embodiments to the respective spectra marked with reference numbers.

FIG. 8 shows excitation spectra of the series of embodiments described in which the proportions of Na and F vary. These excitation spectra are in relation to an emission wavelength of 565 nm. Table 6 again shows the assignment of the various embodiments to the respective spectra marked with reference numbers.

TABLE 6

| Proportion of NaF | Reference number | Reference number |
|---|---|---|
| in % | in FIG. 7 | in FIG. 8 |
| 0.25 | 71 | 81 |
| 0.50 | 72 | |
| 0.75 | 73 | — |
| 1.00 | 74 | |
| 1.15 | 75 | |
| 1.50 | — | 86 |
| 0 | 77 | 87 |

Other preferred embodiments of the garnet luminophore according to the invention have a host lattice of the general chemical formula (Lu₁₋ₖLiₖ)₃(Al_{1-(7/45)·k}P_{k/3})₅O₁₂ and are doped with cerium as an activator at a mole fraction of 0.010.

Various quantities of CeO₂, Al₂O₃, and Li₃PO₄ were weighed and subsequently intermixed to produce these embodiments. Then a quantity of Lu₂O₃ was weighed and mixed with the respective mixture. These mixtures were annealed at a temperature of about 1,650° C., whereby these luminophores were formed. It was particularly the Li₃PO₄ content that was varied in this series of embodiments. The weighed quantities of the parent substances are listed in Table 7.

TABLE 7

| Lu₂O₃ in g | CeO₂ in g | Al₂O₃ in g | Li₃PO₄ in g | Li₃PO₄ in % |
|---|---|---|---|---|
| 354.565 | 3.098 | 152.942 | 10.212 | 2.00 |
| 354.565 | 3.098 | 152.942 | 20.424 | 4.00 |
| 354.565 | 3.098 | 152.942 | 35.742 | 7.00 |
| 354.565 | 3.098 | 152.942 | 51.060 | 10.00 |
| 354.565 | 3.098 | 152.942 | 61.273 | 12.00 |

### LIST OF REFERENCE SYMBOLS

11—Emission spectrum (Lu₁₋ₖLiₖ)₃Al₅(O_{1-(3/8)·k}F_{k/4})₁₂—0.5% LiF
12—Emission spectrum (Lu₁₋ₖLiₖ)₃Al₅(O_{1-(3/8)·k}F_{k/4})₁₂—1.25% LiF
13—Emission spectrum (Lu₁₋ₖLiₖ)₃Al₅(O_{1-(3/8)·k}F_{k/4})₁₂—2.5% LiF
14—Emission spectrum (Lu₁₋ₖLiₖ)₃Al₅(O_{1-(3/8)·k}F_{k/4})₁₂—5.0% LiF
15—Emission spectrum (Lu₁₋ₖLiₖ)₃Al₅(O_{1-(3/8)·k}F_{k/4})₁₂—10.0% LiF
16—Emission spectrum Lu₃Al₅O₁₂
21—Excitation spectrum (Lu₁₋ₖLiₖ)₃Al₅(O_{1-(3/8)·k}F_{k/4})₁₂—0.5% LiF
22—Excitation spectrum (Lu₁₋ₖLiₖ)₃Al₅(O_{1-(3/8)·k}F_{k/4})₁₂—1.25% LiF
23—Excitation spectrum (Lu₁₋ₖLiₖ)₃Al₅(O_{1-(3/8)·k}F_{k/4})₁₂—2.5% LiF
24—Excitation spectrum (Lu₁₋ₖLiₖ)₃Al₅(O_{1-(3/8)·k}F_{k/4})₁₂—5.0% LiF
25—Excitation spectrum (Lu₁₋ₖLiₖ)₃Al₅(O_{1-(3/8)·k}F_{k/4})₁₂—10.0% LiF
26—Excitation spectrum Lu₃Al₅O₁₂
31—Excitation spectrum (Lu₁₋ₖLiₖ)₃Al₅(O_{1-(3/8)·k}F_{k/4})₁₂—0.5% LiF
32—Excitation spectrum (Lu₁₋ₖLiₖ)₃Al₅(O_{1-(3/8)·k}F_{k/4})₁₂—1.25% LiF
33—Excitation spectrum (Lu₁₋ₖLiₖ)₃Al₅(O_{1-(3/8)·k}F_{k/4})₁₂—2.5% LiF
34—Excitation spectrum (Lu₁₋ₖLiₖ)₃Al₅(O_{1-(3/8)·k}F_{k/4})₁₂—5.0% LiF
35—Excitation spectrum (Lu₁₋ₖLiₖ)₃Al₅(O_{1-(3/8)·k}F_{k/4})₁₂—10.0% LiF
36—Excitation spectrum Lu₃Al₅O₁₂
41—Emission spectrum (LuₓGd_{z}Liₖ)₃Al₅(O_{1-(3/8)·k}F_{k/4})₁₂—0.5% LiF
42—Emission spectrum (LuₓGd_{z}Liₖ)₃Al₅(O_{1-(3/8)·k}F_{k/4})₁₂—1.25% LiF
43—Emission spectrum (LuₓGd_{z}Liₖ)₃Al₅(O_{1-(3/8)·k}F_{k/4})₁₂—2.5% LiF
44—Emission spectrum (LuₓGd_{z}Liₖ)₃Al₅(O_{1-(3/8)·k}F_{k/4})₁₂—5.0% LiF
45—Emission spectrum (LuₓGd_{z}Liₖ)₃Al₅(O_{1-(3/8)·k}F_{k/4})₁₂—10.0% LiF
46—Emission spectrum (LuₓGd_{z})₃Al₅O₁₂
51—Excitation spectrum (LuₓGd_{z}Liₖ)₃Al₅(O_{1-(3/8)·k}F_{k/4})₁₂—0.5% LiF
52—Excitation spectrum (LuₓGd_{z}Liₖ)₃Al₅(O_{1-(3/8)·k}F_{k/4})₁₂—1.25% LiF
53—Excitation spectrum (LuₓGd_{z}Liₖ)₃Al₅(O_{1-(3/8)·k}F_{k/4})₁₂—2.5% LiF
54—Excitation spectrum (LuₓGd_{z}Liₖ)₃Al₅(O_{1-(3/8)·k}F_{k/4})₁₂—5.0% LiF
55—Excitation spectrum (LuₓGd_{z}Liₖ)₃Al₅(O_{1-(3/8)·k}F_{k/4})₁₂—10.0% LiF
56—Excitation spectrum (LuₓGd_{z})₃Al₅O₁₂
61—Excitation spectrum (LuₓGd_{z}Liₖ)₃Al₅(O_{1-(3/8)·k}F_{k/4})₁₂—0.5% LiF
62—Excitation spectrum (LuₓGd_{z}Liₖ)₃Al₅(O_{1-(3/8)·k}F_{k/4})₁₂—1.25% LiF
63—Excitation spectrum (LuₓGd_{z}Liₖ)₃Al₅(O_{1-(3/8)·k}F_{k/4})₁₂—2.5% LiF
64—Excitation spectrum (LuₓGd_{z}Liₖ)₃Al₅(O_{1-(3/8)·k}F_{k/4})₁₂—5.0% LiF
65—Excitation spectrum (LuₓGd_{z}Liₖ)₃Al₅(O_{1-(3/8)·k}F_{k/4})₁₂—10.0% LiF
66—Excitation spectrum (LuₓGd_{z})₃Al₅O₁₂
71—Emission spectrum (Y₁₋ₖNaₖ)₃Al₅(O_{1-(3/8)·k}F_{k/4})₁₂—0.25% NaF
72—Emission spectrum (Y₁₋ₖNaₖ)₃Al₅(O_{1-(3/8)·k}F_{k/4})₁₂—0.50% NaF
73—Emission spectrum (Y₁₋ₖNaₖ)₃Al₅(O_{1-(3/8)·k}F_{k/4})₁₂—0.75% NaF
74—Emission spectrum (Y₁₋ₖNaₖ)₃Al₅(O_{1-(3/8)·k}F_{k/4})₁₂—1.00% NaF
75—Emission spectrum (Y₁₋ₖNaₖ)₃Al₅(O_{1-(3/8)·k}F_{k/4})₁₂—1.15% NaF
77—Emission spectrum Y₃Al₅O₁₂
81—Excitation spectrum (Y₁₋ₖNaₖ)₃Al₅(O_{1-(3/8)·k}F_{k/4})₁₂—0.25% NaF
86—Excitation spectrum (Y₁₋ₖNaₖ)₃Al₅(O_{1-(3/8)·k}F_{k/4})₁₂—1.50% NaF
87—Excitation spectrum Y₃Al₅O₁

1. A garnet luminophore excited in a first wavelength range by electromagnetic radiation, resulting in an electromagnetic radiation emitted by the garnet luminophore in a second wavelength range, wherein said garnet luminophore is activated with trivalent cerium and has a host lattice of the following general chemical formula:
(LuₓY_{y}Gd_{z}AKₖ)₃(Al_{b}B_{c}P_{d})₅(OₑX_{f})₁₂
wherein:
AK=one or several alkaline metals selected from the group including the elements Li, Na, and K;
B=Ga and/or In;
X=one or several halogens selected from the group including the elements F, Cl, and Br;
0≦x, y, z<1;
x+y+z+k=1;
0<k<1;
0≦b≦1;
0≦c≦1;
0<b+c;
0≦d<1;
b+c+d≦1;
0<e≦1;
0<f<1; and
e+f≦1.

2. The garnet luminophore according to claim 1, wherein:
d=0;
b+c=1;
f=k/4; and
e=1−(3/8)·k;
resulting in the following general chemical formula of the host lattice:
(LuₓY_{y}Gd_{z}AKₖ)₃(Al_{b}B_{1-b})₅(O_{1-(3/8)·k}X_{k/4})₁₂.

3. A garnet luminophore excited in a first wavelength range by electromagnetic radiation, resulting in an electromagnetic radiation emitted by the garnet luminophore in a second wavelength range, wherein said garnet luminophore is activated with trivalent cerium and has a host lattice of the following general chemical formula:
(LuₓY_{y}Gd_{z}AKₖ)₃(Al_{b}B_{c}P_{d})₅(OₑX_{f})₁₂
wherein:
AK=one or several alkaline metals selected from the group including the elements Li, Na, and K;
B=Ga and/or In;
X=one or several halogens selected from the group including the elements F, Cl, and Br;
0≦x, y, z<1;
x+y+z+k=1;
0<k<1;
0≦b≦1;
0≦c≦1;
0<b+c;
0<d<1;
b+c+d≦1;
0<e≦1;
0≦f<1; and
e+f≦1.

4. The garnet luminophore according to claim 3, wherein:
e=1;
f=0;
d=k/3; and
b=1−c−(7/45)·k;
resulting in the following general chemical formula of the host lattice:
(LuₓY_{y}Gd_{z}AKₖ)₃(Al_{1-c-(7/45)·k}B_{c}P_{k/3})₅O₁₂.

5. The garnet luminophore according to claim 1, wherein the wildcard symbol AK stands for Li or Na.

6. The garnet luminophore according to claim 2, wherein the wildcard symbol X stands for F.

7. The garnet luminophore according to claim 1, wherein a mean wavelength of the second wavelength range is between 500 nm and 600 nm.

8. A method for producing a garnet luminophore, comprising the following steps:
Providing at least one compound including Lu, Y, and/or Gd and at least one compound including Al, Ga, and/or In, wherein at least one of the compounds is made up of an oxide;
Providing a compound including Ce;
Providing a compound of the general chemical formula AKX, wherein AK stands for one or several alkaline metals selected from the group including the elements Li, Na, and K, and X stands for a halogen selected from the group including the elements F, Cl, and Br;
Grinding and mixing of the chemical compounds provided into a mixture;
Heating of the mixture to a temperature of more than 1,400° C., whereby the mixture reacts to form a garnet luminophore; and
Cooling of the garnet luminophore.

9. A light source with a garnet luminophore according to claim 1 and with a radiation source for emitting an electromagnetic radiation in a first wavelength range.

10. The light source according to claim 9, wherein the second wavelength range of the garnet luminophore has a maximum in the green spectral region of the light spectrum, and in that the light source includes a second conversion luminophore which can be excited by the radiation that can be emitted from the radiation source, whereby the second conversion luminophore can emit electromagnetic radiation in the orange and/or red spectral regions of the light spectrum.

11. The light source according to claim 9, wherein said light source is formed by a LED or by a LED backlight for a liquid crystal display.
